(19) United States
(12) Patent Application Publication
(10) Pub. No.: US 2009/0008063 A1
(43) Pub. Date: Jan. 8, 2009

(54) System and Method for Passive Cooling Using a Non-Metallic Wick

(75) Inventors: Mauricio A. Salinas, McKinney, TX (US); Richard M. Weber, Prosper, TX (US); Byron Elliott Short, JR., Fairview, TX (US)

Correspondence Address: BAKER BOTTS LLP, 2001 ROSS AVENUE, 6TH FLOOR, DALLAS, TX, 75201-2980, US

(73) Assignee: Raytheon Company, Waltham, MA (US)

(21) Appl. No.: 11/773,267

(22) Filed: Jul. 3, 2007

(51) Int. Cl. F28D 15/00; H05K 7/20

(52) U.S. Cl. 165/104.26; 165/80.4; 165/104.33; 361/700

(57) ABSTRACT

According to an embodiment of the invention, a cooling system for a heat-generating device comprises a base plate, a fluid transfer chamber, a non-metallic wicking material, and a coolant. The base plate is in thermal communication with a heat generating structure and is operable to communicate thermal energy from the heat-generating device. The non-metallic wicking material and the coolant are disposed within the fluid transfer chamber. The non-metallic wicking material wicks a portion of the coolant towards a portion of the base plate communicating the thermal energy. The portion of the coolant absorb at least a portion of the thermal energy communicated from the heat-generating device. The coolant comprising at least an alcohol and at least one additional fluid.

### TECHNICAL FIELD

This invention relates generally to cooling and, more particularly, to a system and method for passive cooling using a non-metallic wick.

### BACKGROUND

Electronic devices generate thermal energy due to, among other things, a resistance to a flow of electricity by components within the electronic device. The thermal energy or heat generated by such electronic devices can diminish the performance and reliability of the electronic devices. Accordingly, cooling systems are used to dissipate the thermal energy or heat.

### SUMMARY

According to an embodiment of the invention, a cooling system for a heat-generating device comprises a base plate, a fluid transfer chamber, a non-metallic wicking material, and a coolant. The base plate is in thermal communication with a heat generating structure and is operable to communicate thermal energy from the heat-generating device. The non-metallic wicking material and the coolant are disposed within the fluid transfer chamber. The non-metallic wicking material wicks a portion of the coolant towards a portion of the base plate communicating the thermal energy. The portion of the coolant absorb at least a portion of the thermal energy communicated from the heat-generating device. The coolant comprising at least an alcohol and at least one additional fluid.

Certain embodiments of the invention may provide numerous technical advantages. For example, a technical advantage of one embodiment may include the capability to passively cool a heat-generating device with a non-metallic wicking device element. Other technical advantages of other embodiments may include the capability to cool a heat-generating device with a ceramic wicking material passively pumping a coolant mixture of water and alcohol. Still yet other technical advantages of other embodiments may include the capability to mix methanol or ethanol with water in a coolant mixture to carry the water through a wicking material towards an area of thermal energy generated by a heat-generating device, the thermal energy evaporating the coolant mixture.

Although specific advantages have been enumerated above, various embodiments may include all, some, or none of the enumerated advantages. Additionally, other technical advantages may become readily apparent to one of ordinary skill in the art after review of the following figures and description.

### BRIEF DESCRIPTION OF THE DRAWINGS

For a more complete understanding of example embodiments and their advantages, reference is now made to the following description, taken in conjunction with the accompanying drawings, in which:

FIG. 1 illustrates a conventional heat exchanger;

FIG. 2 is a cross-sectional view of a cold plate having a non-metallic wicking element, according to an embodiment of the invention; and

FIG. 3 is a cross-sectional view of a cold plate showing the movement of liquid fluid, vapor fluid, and heat or thermal energy, according to an embodiment of the invention.

### DETAILED DESCRIPTION

It should be understood at the outset that although example embodiments are illustrated below, the present invention may be implemented using any number of techniques, whether currently known or in existence. The present invention should in no way be limited to the example embodiments, drawings, and techniques illustrated below, including the embodiments and implementations illustrated and described herein. Additionally, the drawings are not necessarily drawn to scale.

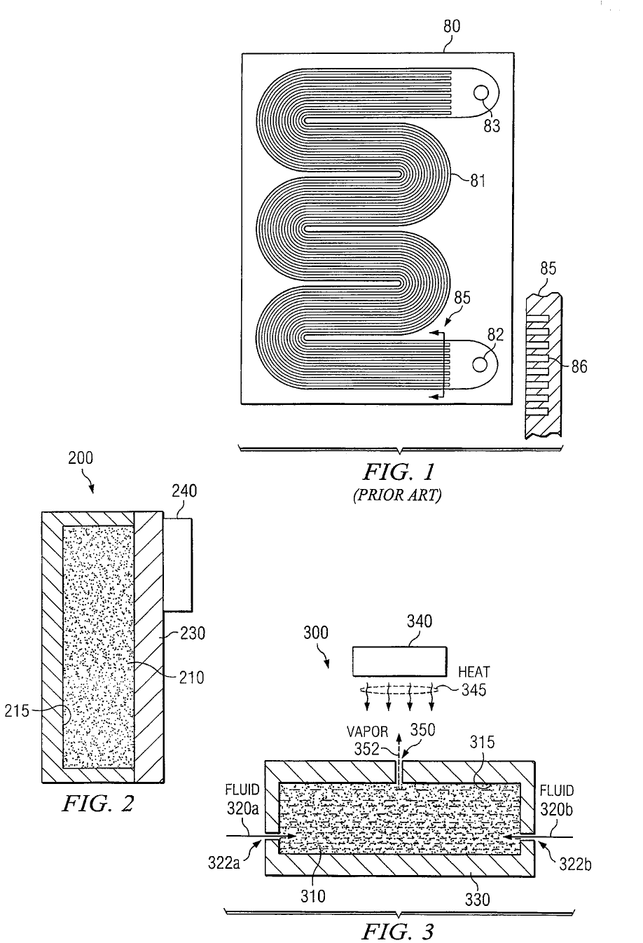

A conventional method of cooling higher heat level electronic devices is to couple the electronic device to a heat exchanger or cold plate which may be of the type shown in FIG. 1. With reference to FIG. 1, heat exchanger 80 includes a flow path 81 through which may flow a heat transfer fluid to absorb heat produced by an electronic device (not shown) which is coupled to heat exchanger 80. Heat exchanger 80 has an inlet 82 through which a heat transfer fluid is introduced into flow path 81 and an outlet 83 through which the heat transfer fluid exits flow path 81. As shown in the enlarged cross-sectional partial view 85, provided in FIG. 1, the flow path may comprise a plurality of channels 86 through which the heat transfer fluid flows.

For significantly higher heat loads, a different type of heat transfer fluid or coolant may be required that absorbs heat by changing from a liquid to a vapor. These heat exchangers are sometimes referred to as two-phase cold plates. Referring to FIG. 1, with a two-phase cold plate the heat transfer fluid enters the heat exchanger 80 through inlet 82 as a liquid. After absorbing heat, the heat transfer fluid becomes a vapor and exits through outlet 83.

While providing improvements over single-phase heat exchangers, conventional two-phase heat exchangers may also have drawbacks. As one example, in conventional two-phase heat exchangers, the liquid component of the coolant tends to sink to the bottom of the fluid flow passages within the heat exchanger. As a result, some heated areas are not presented with liquid to absorb the heat or thermal energy. Such a condition becomes particularly troublesome near the outlet of such conventional two-phase heat exchangers because the coolant has an even greater concentration of vapor in this area.

As another example, conventional heat exchangers are sensitive to gravity and acceleration induced forces that tend to cause the liquid component of the coolant to be forced into certain areas of the heat exchanger, depending upon the orientation of the heat exchanger. For example, if the heat exchanger shown in FIG. 1 was positioned vertically such that the outlet was positioned above the inlet, gravity would tend to force the liquid component of the coolant toward the bottom of the heat exchanger passages (i.e., toward the inlet), thereby exacerbating the problem of high vapor concentrations in hot spots near the outlet. External forces may be magnified in certain applications such as, for example, use of the heat exchanger in a high-performance military aircraft or single use or expendable weapons.

Accordingly, teachings of certain embodiments recognize a two-phase cooling system that helps ensure that coolant is adequately provided to pertinent portions of the heat exchanger. Additionally, teachings of other embodiments recognize that coolant mixtures can provide the desired transfer characteristics for the coolant while, at the same time, providing the desired heat transfer characteristics of the coolant.

FIG. 2 is a cross-sectional view of a cold plate 200 having a non-metallic wicking element, according to an embodiment of the invention. The cold plate 200 of FIG. 2 includes a wicking element 210 disposed within a fluid chamber 215, a base plate 230, and a heat-generating device 240. Among other things, the cold plate 200 may be configured to not only reduce a creation of hot spots, but also to reduce negative effects of gravity and other forces that may effect the heat transfer performance of a two-phase cold plate.

According to particular embodiments, the wicking element 210 may be incorporated into the base plate 230. For example in particular embodiments, the base plate 230 may create at least a portion of the chamber 215 within which the wicking element 210 resides.

In particular embodiments, the wicking element 210 provide a capillary action, which may draw liquid coolant into liquid-poor areas of the fluid transfer chamber 215 against the forces of vaporized coolant, gravity and/or any other forces caused by orientation and application of the cold plate 200. With such a passive cooling mechanism, particular embodiments may not need a control loop, a control algorithm, a monitoring device, a power supply, or any other electronics to operate cold plate 200.

In particular embodiments, wicking element 210 may be made of a non-metallic porous material, such as ceramic or ceramic fibers. In other embodiments, wicking element 210 may include a microporous material made of microporous aluminum, bronze, copper, or composite felts. In yet other embodiments, wicking element 210 may include other suitable types of wicking material. Coolant may fill the voids within the porous wicking element 210, creating a capillary action that may enhance the even distribution of coolant within cold plate 200. That is, the capillary action of wicking element 210 may wick the coolant from relatively liquid-rich areas of the fluid transfer chamber 215 towards relatively liquid-poor areas of the fluid transfer chamber 215.

The base plate 230 may be made of any type of material that conducts thermal energy or heat. For example, base plate 230 may be made of aluminum or copper. In particular embodiments, the surface of the base plate 230 that is in thermal communication with the heat-generating device may be relatively thicker than the remaining walls of the fluid transfer chamber 215 surrounding the wicking element 210. This may help to more evenly distribute thermal energy generated by the heat-generating device 240 in particular embodiments.

In particular embodiments, the cold plate 200 may include an inlet to allow coolant in the form of a liquid to be added to the fluid transfer chamber 215 and an outlet to allow coolant in the form of a vapor to exit the fluid transfer chamber 215. In some embodiments, the outlet may vent to the ambient air or atmosphere. In other embodiments, the outlet may vent to a condenser which may condense the vapor back into a fluid state so that coolant may re-enter the fluid transfer chamber 215, for example, through the above-referenced inlet.

The heat-generating device 240 may be any of a variety of different devices, including, but not limited to, an electronic device, slats of a satellite, a leading edge of an expendable weapon or aircraft, a phased array radar, a time variant heat load, a spatially variant heat load or any other device or a component which may produce an undesirable amount of thermal energy.

In particular embodiments, the heat-generating device 240 may generate thermal energy that is transferred to the base plate 230 and the coolant within the fluid-transfer chamber 215. As the coolant in a liquid state absorbs the thermal energy, the coolant may vaporize, thereby removing the liquid state of the coolant from the vicinity. During such an occurrence, the capillary action of the wicking element 210 tends to transport the liquid component of the coolant from liquid-rich areas into the liquid-poor area created from the vaporization of the fluid by the thermal energy from the heat-generating device 240.

As alluded to above, one technique for removing thermal energy created by the heat-generating device 240 is to vaporize a liquid which is in contact with the thermal energy from the heat-generating device 240. As the liquid vaporizes, it inherently absorbs heat or thermal energy to effectuate such vaporization. The amount of heat or thermal energy that can be absorbed per unit volume of a liquid is commonly known as the latent heat of vaporization of the liquid. The higher the latent heat of vaporization, the larger the amount of heat that can be absorbed per unit volume of liquid being vaporized. The coolant used in particular embodiments may be a two phase coolant which absorbs thermal energy to engage in vaporizing the coolant to change it from a liquid to a gas.

As thermal energy from the heat-generating device 240 vaporizes the coolant, the area adjacent the heat-generating device 240 becomes liquid-poor. Accordingly, the capillary action supplied by the wicking element 210 begins transporting additional liquid coolant to the liquid-poor area adjacent the heat-generating device 240. Upon the new coolant being wicked to the liquid-poor area adjacent the heat-generating device 240, the new coolant is vaporized and the cycle continues.

In particular embodiments, the coolant may be a mixture of two or more fluids including, but not limited to water, ethanol, methanol, FC-72, ethylene glycol, propylene glycol, fluoroinert or any suitable antifreeze. In particular embodiments, the water may provide desirable heat transfer characteristics (e.g., desired latent heat of vaporization) while another fluid (such as ethanol or methanol) may provide desirable fluid transfer characteristics to transfer the coolant through the wicking material 210. In other words, in particular embodiments, a particular fluid (e.g., ethanol, methanol, or the like) may be mixed with water to serve a wicking transport material for the water, which has desirable heat transfer characteristics in absorbing the thermal energy from the heat-generating device.

As reference above, the wicking element 210 may capture some of the liquid portion and passively pump it to areas that are liquid-poor (e.g., the areas where thermal energy from the heat-generating device 240 has vaporized the coolant), using a capillary action. The capillary action of wicking element 210 may also assist in distributing the liquid coolant during accelerations and adverse orientations. This may be useful, for example, in high-performance military aircraft or expendable weapons. Wicking element 210 may also enhance the two-phase heat exchange performance of a cold plate 200 by reducing the amount of area temporarily void of coolant during a high-speed maneuver. Another application in which this may be desirable is in space or other low gravity environments. For example, cold plate 200 may be used with the power slats of a satellite. Cold plate 200 may also be used with an active electronically scanned array (AESA) radar.

FIG. 3 is a cross-sectional view of a cold plate 300 showing the movement of liquid fluid 320, vapor fluid 352, and heat or thermal energy 345, according to an embodiment of the invention. The cold plate 300 of FIG. 3 may include similar features and operate in a similar fashion to the cold plate 200 of FIG. 2. For example, the cold plate 300 includes a wicking element 310 disposed within a fluid chamber 315, a base plate 330, and a heat-generating device 340.

In the embodiment of FIG. 3, thermal energy or heat 345 is depicted as flowing from the heat-generating device 340. In particular embodiments, the heat-generating device 340 may be directly adjacent the base plate 330. In other embodiments, the heat-generating device 340 may be removed from the base plate 330.

In the embodiment of FIG. 3, the thermal energy or the heat 345 is depicted as being thermally communicated to the base plate 330. This may cause liquid fluid 320 in the adjacent area of the chamber 315 to vaporize (as it absorbs the thermal energy), creating a liquid-poor area. As this coolant vaporizes the capillary action of the wicking element 310 transports additional liquid fluid 320 towards the liquid-poor area. Then, as this additional liquid fluid 320 picks up additional heat or thermal energy 340, the additional liquid fluid 320 vaporizes. Thus, in FIG. 3, wicking element 310 helps transport the liquid fluid 320 to the middle of the fluid transfer chamber 315 (e.g., internal side of base plate 330 where the thermal energy or the heat 345 is contacting base plate 330). In particular embodiments, the wicking element 310 may also function as a fin stock that increases the area from which thermal energy or heat is absorbed.

Both the source of the liquid fluid 320 and the destination of the vapor fluid 352 may vary depending on the configuration, features and needs addressed by cold plate 300. For example, in some embodiments cold plate 300 may be used in a single-use setting, such as with expendable weapons. In particular embodiments, the cold plate 300 may be used in a repeated-use setting where the coolant may be replaced, such as on an aircraft where coolant can be replaced when fuel, oil or other aircraft fluids are checked/replaced. In some embodiments, the cold plate 300 may be used in a continuous-use setting where replacing the coolant may be difficult, such as on a satellite.

To meet the needs of a satellite application, in particular embodiments the cold plate 300 may be self contained and thereby capable of reusing the coolant. Accordingly, the cold plate 300 may be pre-loaded with a coolant that once vaporized is condensed and then reused. More specifically, the cold plate 300 may include a coolant reservoir (not depicted) that may be able to pass the liquid fluid 320 to the wicking element 310 through inlets 322a, 322b. As the liquid fluid 320 vaporizes, the liquid fluid 320 may exit the base plate 330 through exits 350, carrying with it the heat absorbed from the thermal energy or heat 345. The capillary action of the wicking element 310 moves the liquid fluid 320 to the liquid-poor area created by the vaporization of the liquid fluid 320. This replaces the coolant lost via vapor fluid 352. In other words, wicking element 310 captures the liquid fluid 320 and passively pumps it to the areas that are liquid-poor. Upon exiting through the exit 350, the vapor fluid 352 may be captured in a recovery system. The recovery system may comprise a loop which circulates the vapor fluid 352 to a condenser, heat exchanger, or other suitable device. The condenser sufficiently cools the vapor fluid 352 so that it condenses back into a liquid. To cool the vapor fluid 352, the condenser may engage in a transfer of thermal energy into the ambient air. Once cooled, the liquid fluid 320 may return to the fluid transfer chamber 315 (e.g., via the inlets 322a, 322b) where it may be available to once again be wicked to a liquid-poor area. A loop such as this may be passively powered or actively pumped.

In a single-use or repeated-use application, the cold plate 300 may not recycle its coolant. This can decrease the weight and size of the cold plate 300 by removing the need to have a condenser. In particular, embodiments, this may be desirable for use with expendable weapons or aircraft. As the thermal energy or heat 345 vaporizes the liquid fluid 320, the vapor fluid 352 is released into the atmosphere. As an example, the exit 350 may be able to direct the vapor fluid 352 into the atmosphere.

Furthermore, in single-use applications the amount of coolant needed may be known (e.g., based on the amount of fuel the expendable weapon has, the time of flight may be known and thus the amount of coolant needed). Thus, the cold plate 300 may not include inlets; all the coolant needed for the single-use application may be contained within the fluid transfer chamber 315. However, in a repeated-use application it may not be as easy to determine the amount of coolant that may be needed. Thus, it may be desirable to use a coolant reservoir that can store enough coolant for multiple uses and includes a way to recharge or replace lost coolant.

The configurations of the cold plates depicted herein are provided by way of example only, and may be modified within the scope of the present invention. For example, the base plate 330 and the wicking element 310 may be provided in any of a variety of configurations. Also, while the cold plates 200, 300 have been shown as having a rectangular cross-section, the cross-sectional shape for this, or any other configuration, may be varied depending upon the desired application.

Although the present invention has been described with several embodiments, a myriad of changes, variations, alterations, transformations, and modifications may be suggested to one skilled in the art, and it is intended that the present invention encompass such changes, variations, alterations, transformation, and modifications as they fall within the scope of the appended claims.

1. A cooling system for a heat-generating device, comprising:
a base plate in thermal communication with a heat generating structure, the base plate operable to communicate thermal energy from the heat-generating device;
a fluid transfer chamber; and
a ceramic wicking material and a coolant disposed within the fluid transfer chamber, the non-metallic wicking material operable to wick a portion of the coolant towards a portion of the base plate communicating the thermal energy, the portion of the coolant operable to absorb at least a portion of the thermal energy communicated from the heat-generating device, the portion of the coolant in absorbing at least a portion of the thermal energy communicated from the heat-generating device vaporizing, and the coolant comprising at least an alcohol and at least one additional fluid.

2. The apparatus of claim 1, wherein the alcohol is ethanol.

3. The apparatus of claim 1, wherein the alcohol is methanol.

4. The apparatus of claim 1, wherein the base plate comprises a vent operable to receive vaporized coolant yielded from absorbing at least a portion of the thermal energy.

5. The apparatus of claim 4, wherein:
the vent is open to ambient air; and
the vaporized coolant is expended to the ambient air.

6. The apparatus of claim 4, wherein:
the vent is coupled to a condenser;
the condenser is coupled to the fluid-transfer chamber; and
the vaporized coolant is condensed by the condenser and returned to the fluid-transfer chamber.

7. A cooling system for a heat-generating device, comprising:
a base plate in thermal communication with a heat generating structure, the base plate operable to communicate thermal energy from the heat-generating device;
a fluid transfer chamber; and
a non-metallic wicking material and a coolant disposed within the fluid transfer chamber, the non-metallic wicking material operable to wick a portion of the coolant towards a portion of the base plate communicating the thermal energy, the portion of the coolant operable to absorb at least a portion of the thermal energy communicated from the heat-generating device, and the coolant comprising at least an alcohol and at least one additional fluid.

8. The apparatus of claim 7, wherein the non-metallic wicking material comprises ceramic.

9. The apparatus of claim 8, wherein the non-metallic wicking element comprises ceramic fiber.

10. The apparatus of claim 7, wherein the alcohol is ethanol.

11. The apparatus of claim 7, wherein the alcohol is methanol.

12. The apparatus of claim 7, wherein the portion of the coolant in absorbing at least a portion of the thermal energy communicated from the heat-generating device vaporizes in a boiling heat transfer.

13. The apparatus of claim 12, wherein the base plate comprises a vent operable to receive vaporized coolant yielded from absorbing at least a portion of the thermal energy.

14. The apparatus of claim 13, wherein:
the vent is open to ambient air; and
the vaporized coolant is expended to the ambient air.

15. The apparatus of claim 13, wherein:
the vent is coupled to a condenser;
the condenser is coupled to the fluid-transfer chamber; and
the vaporized coolant is condensed by the condenser and returned to the fluid-transfer chamber.

16. The apparatus of claim 7, wherein the heat-generating device is selected from the group consisting of an electronic device, a satellite, an expendable weapon, an aircraft, a phased array radar, a time variant heat load, and a spatially variant heat load.

17. The apparatus of claim 7, wherein the base plate is made from a material selected from the group consisting of aluminum, copper, aluminum silicon carbide, and composite materials.

18. A method of dissipating thermal energy from a heat-generating device, the method comprising:
receiving thermal energy from a heat-generating device;
wicking, with a non-metallic wicking material, coolant towards the thermal energy;
absorbing with the coolant at least a portion of the thermal energy received from the heat-generating device in a boiling heat transfer to yield a vaporized coolant; and
releasing the vaporized coolant to ambient air.

19. The method of claim 18, wherein the non-metallic wicking element comprises ceramic.

20. The method of claim 18, wherein the coolant comprising at least an alcohol and at least one additional fluid.
